(19) United States
(12) Patent Application Publication
(10) Pub. No.: US 2023/0179162 A1
(43) Pub. Date: Jun. 8, 2023

(54) DIFFERENTIAL STACKED POWER AMPLIFIER WITH INDUCTIVE GAIN BOOSTING

(71) Applicant: GlobalFoundries U.S. Inc., Malta, NY (US)

(72) Inventors: Payam Mehr, Irvine, CA (US); Nader Rohani, Scottsdale, AZ (US)

(73) Assignee: GlobalFoundries U.S. Inc., Malta, NY (US)

(21) Appl. No.: 17/545,057

(22) Filed: Dec. 8, 2021

(51) Int. Cl. H03G 3/30; H03F 3/45

(52) U.S. Cl. CPC H03G 3/3042; H03F 3/45179; H03F 2200/451; H03G 2201/103

(57) ABSTRACT

An exemplary structure has an output stage; a driver stage; and a power stage connected between the driver stage and the output stage. The power stage includes a first transistor and a second transistor connected in series between the driver stage and the output stage. The power stage also includes a third transistor and a fourth transistor connected in series between the driver stage and the output stage. An inductor has a first terminal electrically connected to a first node between the first transistor and the second transistor and a second terminal electrically connected to a second node between the third transistor and the fourth transistor. The inductor is configured to provide impedance matching between common-gate stages of the power stage.

### BACKGROUND

The present disclosure relates to amplifiers, and, more specifically, to power amplifiers.

Due to the fast-growing demand of wireless communication, complementary metal oxide semiconductor (CMOS) transceivers have been developed for radio frequency (RF) applications and have become available for the commercial market. However, there are still technical obstacles to achieve widespread application of millimeter-wave (mmWave) (e.g., 30-300 GHz) wireless applications, especially in the design of Power Amplifiers (PAs).

### SUMMARY

According to an exemplary embodiment herein, a structure has an output stage; a driver stage; and a power stage connected between the driver stage and the output stage. The power stage includes a first transistor and a second transistor connected in series between the driver stage and the output stage. The power stage also includes a third transistor and a fourth transistor connected in series between the driver stage and the output stage. An inductor has a first terminal electrically connected to a first node between the first transistor and the second transistor and a second terminal electrically connected to a second node between the third transistor and the fourth transistor.

According to other exemplary embodiment herein, a structure has an output stage; a driver stage; and a power stage connected between the driver stage and the output stage. The power stage includes a first transistor and a second transistor connected in series between the driver stage and the output stage. The power stage also includes a third transistor and a fourth transistor connected in series between the driver stage and the output stage. An inductor has a first terminal electrically connected to a first node between the first transistor and the second transistor and a second terminal electrically connected to a second node between the third transistor and the fourth transistor. The first transistor has a first gate; the second transistor has a second gate; the third transistor has a third gate; and the fourth transistor has a fourth gate. The first gate and the third gate receive a first gate voltage such that the first transistor and the second transistor make up a first common-gate stage of the power stage. The second gate and the fourth gate receive a second gate voltage such that the second transistor and the fourth transistor make up a second common-gate stage of the power stage. The inductor is configured to provide impedance matching between the first common-gate stage and the second common-gate stage.

According to other exemplary embodiment herein, a structure has an output stage; a driver stage; and a power stage connected between the driver stage and the output stage. The power stage includes a first transistor and a second transistor connected in series between the driver stage and the output stage. The power stage also includes a third transistor and a fourth transistor connected in series between the driver stage and the output stage. An inductor has a first terminal electrically connected to a first node between the first transistor and the second transistor and a second terminal electrically connected to a second node between the third transistor and the fourth transistor. The first transistor, the second transistor, the third transistor, and the fourth transistor are n-type field effect transistors. The first transistor has a first gate; the second transistor has a second gate; the third transistor has a third gate; and the fourth transistor has a fourth gate. The first gate and the third gate receive a first gate voltage such that the first transistor and the second transistor make up a first common-gate stage of the power stage. The second gate and the fourth gate receive a second gate voltage such that the second transistor and the fourth transistor make up a second common-gate stage of the power stage. The inductor is configured to provide impedance matching between the first common-gate stage and the second common-gate stage.

### BRIEF DESCRIPTION OF THE DRAWINGS

The devices and methods herein will be better understood from the following detailed description with reference to the drawings, which are not necessarily drawn to scale and in which:

FIG. 1 is a schematic diagram of an exemplary power amplifier according to devices and methods herein;

FIG. 2 is an illustration of a power amplifier showing parasitic capacitances; and

FIG. 3 is a simplified illustration of the power amplifier of FIG. 1 according to devices and methods herein.

### DETAILED DESCRIPTION

The disclosure will now be described with reference to a differential stacked power amplifier that uses a differentially connected inductor at the drain of the first common gate transistors. While the disclosure will be described hereinafter in connection with specific devices and methods thereof, it will be understood that limiting the disclosure to such specific devices and methods is not intended. On the contrary, it is intended to cover all alternatives, modifications, and equivalents as may be included within the spirit and scope of the disclosure as defined by the appended claims.

For a general understanding of the features of the disclosure, reference is made to the drawings. The drawings are not to scale; however, in the drawings, like reference numerals have been used throughout to identify identical elements.

It will be readily understood that the devices and methods of the present disclosure, as generally described and illustrated in the drawings herein, may be arranged and designed in a wide variety of different configurations in addition to the devices and methods described herein. Thus, the following detailed description of the devices and methods, as represented in the drawings, is not intended to limit the scope defined by the appended claims but is merely representative of selected devices and methods. The following description is intended only by way of example, and simply illustrates certain concepts of the devices and methods, as disclosed and claimed herein.

As mentioned above, due to the fast-growing demand of wireless communication and mm-wave radar applications, complementary metal oxide semiconductor (CMOS) transceivers have been developed radio frequency (RF) applications and have become available for the commercial market. However, there are still technical obstacles to achieve widespread application of millimeter-wave (mmWave) (e.g., 30-300 GHz) wireless applications, especially in the design of Power Amplifiers (PAs). For example, the gain of a CMOS transistor above approximately 60 GHz is typically small, so multiple-stage design can be employed in order to obtain higher gain. Power combining technology can be a solution to CMOS's low output power; however, the efficiency of a CMOS PA is usually low due to the poor RF performance of the transistor and high power loss associated with the power combining techniques. Techniques, such as multi-stage design further reduce the overall efficiency.

In view of the foregoing, disclosed herein are embodiments of a differential stacked power amplifier with inductive gain boosting for improved performance (e.g., suitable for mm-Wave applications). That is, within the differential stacked power amplifier, performance of the power stage can be improved by inclusion of an inductor. This inductor can be configured to cancel out intrinsic and extrinsic parasitic capacitances, leading to better overall performance. Specifically, by building an LC resonator at the first junction between transformer stages of the power amplifier, reactive (inductive) tuning can be used for complex impedance matching between stages in the differential stacked power amplifier. A differentially connected inductor may be provided at the common-gate stage of the differential stacked PA. In some embodiments, a spiral inductor may be used. This increases the transconductance (gₘ) of the common-gate transistors in the PA, which leads to a higher voltage gain. The higher transconductance (gₘ) suppresses the cascode stage dominant pole and enhances the bandwidth and gain. The differentially connected inductor resonates out the parasitic capacitances at the cascode node

More particularly, according to devices and methods herein, a structure can include an output stage; a driver stage; and a power stage connected between the driver stage and the output stage. The power stage can include a first transistor and a second transistor connected in series between the driver stage and the output stage. The power stage can also include a third transistor and a fourth transistor connected in series between the driver stage and the output stage. An inductor can have a first terminal electrically connected to a first node between the first transistor and the second transistor and a second terminal electrically connected to a second node between the third transistor and the fourth transistor. The first transistor has a first gate; the second transistor has a second gate; the third transistor has a third gate; and the fourth transistor has a fourth gate. The first gate and the third gate receive a first gate voltage such that the first transistor and the second transistor make up a first common-gate stage of the power stage. The second gate and the fourth gate receive a second gate voltage such that the second transistor and the fourth transistor make up a second common-gate stage of the power stage. The inductor may be configured to provide impedance matching between the first common-gate stage and the second common-gate stage.

In some embodiments, the driver stage can include a cross-coupled pair of transistors, sometimes referred to herein as input transistors. The driver stage can be connected between an input stage and the power stage. The input stage can be made up of an input transformer having primary and secondary windings. The primary winding of the input transformer may be connected to a radio frequency input. The output from the primary is coupled to the secondary of the input transformer, which may be connected to the input transistors. The output stage can include an output transformer having primary and secondary windings. The primary winding of the output transformer may be connected to the last transistors of the power stage. The primary winding is coupled to the secondary winding of the output transformer, which may be connected to a radio frequency output. The input and output transformers provide input and output matching networks for the PA. The transformers are used to create impedance matching between the first common-source transistor pair of the power stage and the preceding stage, and between the second common-gate stage and the next stage, respectively.

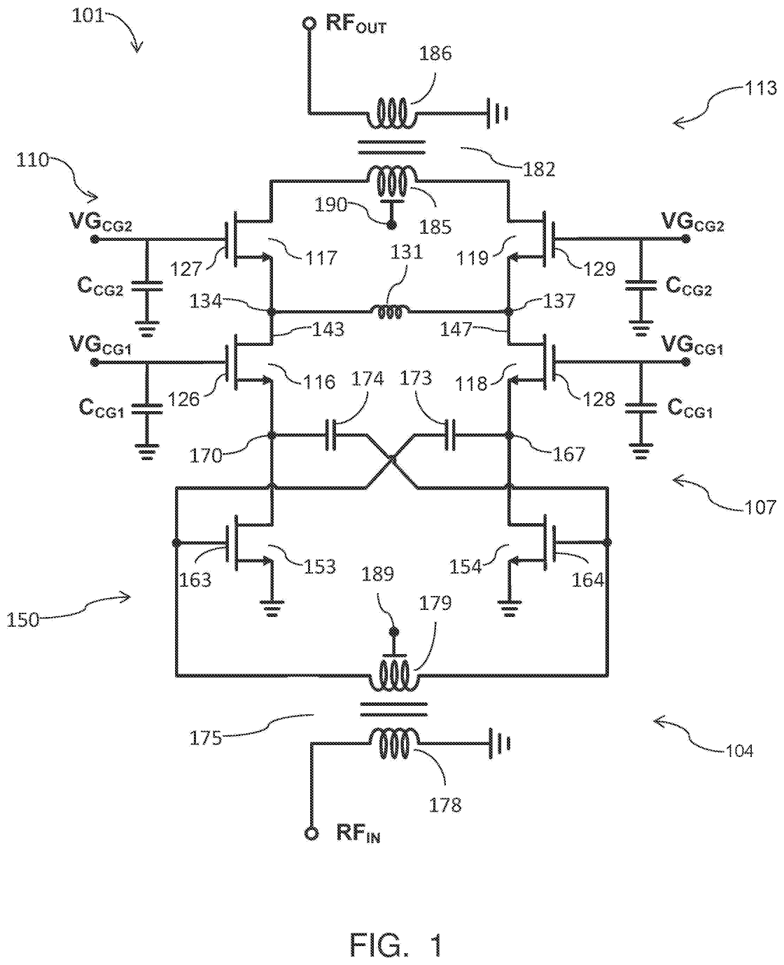

Referring now to the drawings, FIG. 1 is a schematic diagram of an exemplary power amplifier circuit, indicated generally as 101. The power amplifier circuit 101 includes multiple stages. These stages can include, but are not limited to; a radio frequency (RF) input stage 104, a driver stage 107, a power stage 110, and an RF output stage 113. For example, as described in further detail below, the driver stage 107 can include a pair of common-source input transistors, the power stage 110 can include first and the second common-gate like transistors, the RF input stage 104 can be configured to receive an RF input signal, and the RF output stage 113 can be configured to provide impedance matching for the output signal. The driver stage 107 can be connected between the RF input stage 104 and the power stage 110 and can, for example, be configured to regulate current flow through the power amplifier circuit 101. The power stage 110 can be connected between the driver stage 107 and the RF output stage 113 and can, for example, be configured to amplify the input signal, converting it from a lower power RF signal to a higher power RF signal, using inductive gain boosting. The RF output stage 113 can be connected to the power stage 110 and can, for example, be configured to receive and output the higher power output signal.

More particularly, as mentioned above, the power stage 110 can be connected between the driver stage 107 and the output stage 113. The power stage 110 can include a first set of stacked transistors (designated as first transistor 116 and second transistor 117) connected in series on the positive half circuit of the power stage 110 between the driver stage 107 and the output stage 113 and a second set of stacked transistors (designated as third transistor 118 and fourth transistor 119) connected in series on the negative half circuit side of the power stage 110 between the driver stage 107 and the output stage 113. Note, in a differential PA, the positive and negative half circuits are 180 degrees out of phase from an AC point of view.

Within a transistor, the semiconductor (or channel region) is positioned between a conductive “source” region and a similarly conductive “drain” region and when the semiconductor is in a conductive state, the semiconductor allows electrical current to flow between the source and drain. A “gate” is a conductive element that is electrically separated from the semiconductor by a “gate dielectric” and current/voltage within the gate changes the conductivity of the channel region of the transistor. Each transistor 116, 117, 118, 119 of the power stage 110 can be an n-type field effect transistor. In some embodiments, the power amplifier can be implemented using advanced semiconductor-on-insulator processing technology platforms (e.g., a fully-depleted semiconductor-on-insulator (FDSOI) technology platform). Those skilled in the art will recognize that FDSOI is a planar process technology that uses an ultra-thin layer of insulator, called a buried oxide, positioned on top of the base silicon. A very thin optionally un-doped silicon film implements the transistor channel. The details of FDSOI transistors are omitted herefrom to allow the reader to focus on the salient aspects of the systems and methods described herein. Alternatively, the power amplifier could be implemented in any other suitable technology platform.

In the first set of stacked transistors, the first transistor 116 has a first gate 126 and the second transistor 117 has a second gate 127. In the second set of stacked transistors, the third transistor 118 has a third gate 128 and the fourth transistor 119 has a fourth gate 129. The first gate 126 and the third gate 128 receive a first gate voltage (VG_{CG1}) such that the first transistor 116 and the third transistor 118 form a first common-gate like stage of the power stage 110. Similarly, the second gate 127 and the fourth gate 129 receive a second gate voltage (VG_{CG2}) such that the second transistor 117 and the fourth transistor 119 form a second common-gate like stage of the power stage 110.

An inductor 131 can be connected between the first common-gate stage and the second common-gate stage of the power stage 110 with a first terminal being electrically connected to a first node 134 between the first transistor 116 and the second transistor 117 of the first set of stacked transistors and the second terminal being electrically connected to a second node 137 between the third transistor 118 and the fourth transistor 119 of the second set of stacked transistors. The first node 134 can be located at the drain 143 of the first transistor 116 and the second node 137 can be located at the drain 147 of the third transistor 118.

As mentioned above, a driver stage 107 can be connected between the RF input stage 104 and the power stage 110 and can, for example, be configured to regulate current flow through the power amplifier circuit 101. An exemplary driver stage 107 can, as illustrated, include a pair of capacitively cross-coupled transistors 150 (designated as fifth transistor 153 and sixth transistor 154), sometimes referred to herein as input transistors. The fifth transistor 153 is connected in series between the first transistor 116 and ground. The sixth transistor 154 is connected in series between the third transistor 118 and ground. The fifth transistor 153 has a fifth gate 163 and the sixth transistor 154 has a sixth gate 164. The input transistors 150 are capacitively cross-coupled such that the fifth gate 163 is electrically connected to a junction 167 between the third transistor 118 and the sixth transistor 154, and the sixth gate 164 is electrically connected to a junction 170 between the first transistor 116 and the fifth transistor 153. A first neutralization capacitor 173 can be connected between the fifth gate 163 and the junction 167 between the third transistor 118 and the sixth transistor 154. A second neutralization capacitor 174 can be connected between the sixth gate 164 and the junction 170 between the first transistor 116 and the fifth transistor 153. The first and second neutralization capacitors 173, 174 are used to generate increased power gain at the desired frequency of operation (76 GHz-81 GHz). It should be understood that the figures and the above description of the driver stage are not intended to be limiting. Various different driver stage configurations are known in the art and could, alternatively, be incorporated into the disclosed power amplifier where the power stage is configured for inductive gain boosting.

An exemplary RF input stage 104 can be made up of an input transformer 175 having a primary winding 178 and a secondary winding 179. The end terminals of the primary winding 178 of the input transformer 175 can be connected to a radio frequency input (RF_{IN}) and ground, respectively. The primary winding 178 is coupled to the secondary winding 179 of the input transformer 175. The end terminals of the secondary winding 179 can be connected to the driver stage 107. For example, in the exemplary driver stage shown in the figures, the end terminals of the secondary winding 179 could be connected to the input transistors 150, (e.g., to the fifth transistor 153 and sixth transistor 154, respectively). It should be understood that the figures and the above description of the input stage are not intended to be limiting. Various different RF input stage configurations are known in the art and could, alternatively, be incorporated into the disclosed power amplifier where the power stage is configured for inductive gain boosting.

An exemplary RF output stage 113 can include an output transformer 182 having a primary winding 185 and a secondary winding 186. The end terminals of the primary winding 185 of the output transformer 182 can be connected to the power stage and, particularly, to the last transistors of the power stage 110 (i.e., to the second transistor 117 and fourth transistor 119, respectively). The primary winding 185 is coupled to the secondary winding 186 of the output transformer 182 and the secondary winding 186 can have end terminals connected to a radio frequency output (RF_{OUT}) and ground, respectively. It should be understood that the figures and the above description of the output stage are not intended to be limiting. Various different output stage configurations are known in the art and could, alternatively, be incorporated into the disclosed power amplifier where the power stage is configured for inductive gain boosting.

In the above-described power amplifier, the driver stage 107 (e.g., the pair of capacitively cross-coupled transistors 150 thereof) provides a signal at a selected frequency. The ratio K, that is the coupling factor, between the primary windings 178, 185 and the secondary windings 179, 186 for each of the input transformer 175 and the output transformer 182 may be the same and is dependent on the specific design and technology. A first power supply 189 may connected to the center-tap of the secondary winding 179 of the input transformer 175 and a DC bias voltage 190 may be connected to the center-tap of the primary winding 185 of the output transformer 182. RF output from the secondary side of the output transformer 182 can be used, for example, in RADAR or wireless cellular communication applications or other applications as would be known to one of ordinary skill in the art.

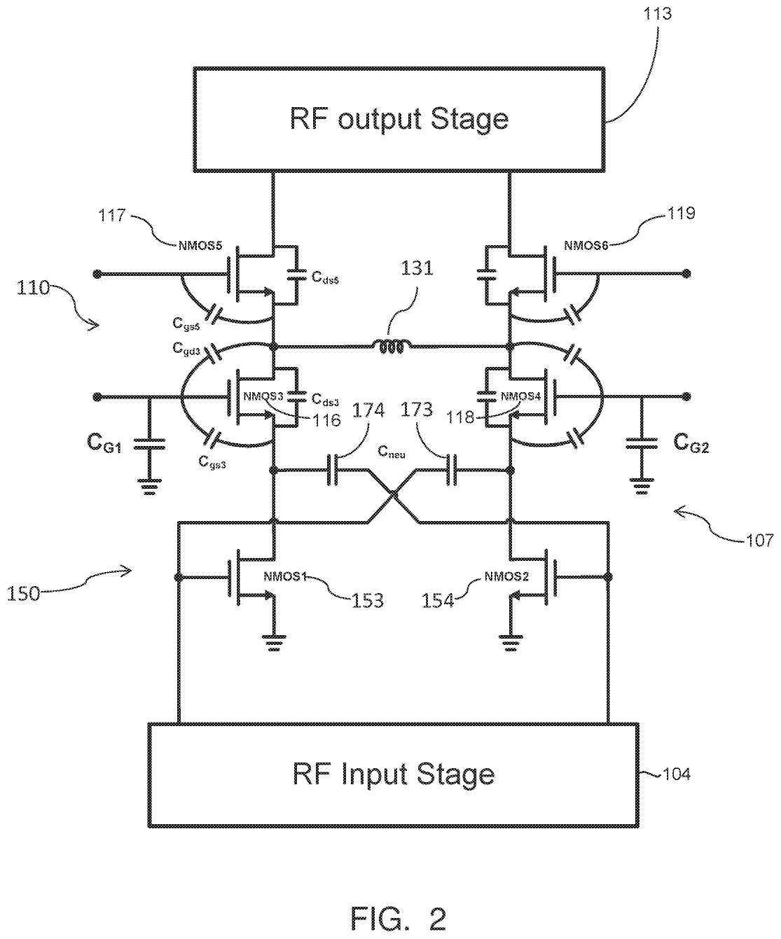

Referring now to FIG. 2, parasitic capacitances affecting the first transistor 116, (indicated as NMOS3) are illustrated as output capacitances C_{gs3}, C_{gd3}, C_{ds3} between the gate and source, gate and drain, and drain and source, respectively of NMOS3 and input capacitance C_{gs5} from the second transistor 117 (indicated as NMOSS). Capacitors C_{G1} and C_{G2} are connected between the gates of the first transistor 116 and the third transistor 118, respectively and the ground. These capacitors (C_{G1} and C_{G2}) improve the gain and reliability of the pair of transistors 116, 118. And, capacitors (C_{G1} and C_{G2}) change the parasitic capacitance associated with the first node 134 and the second node 137.

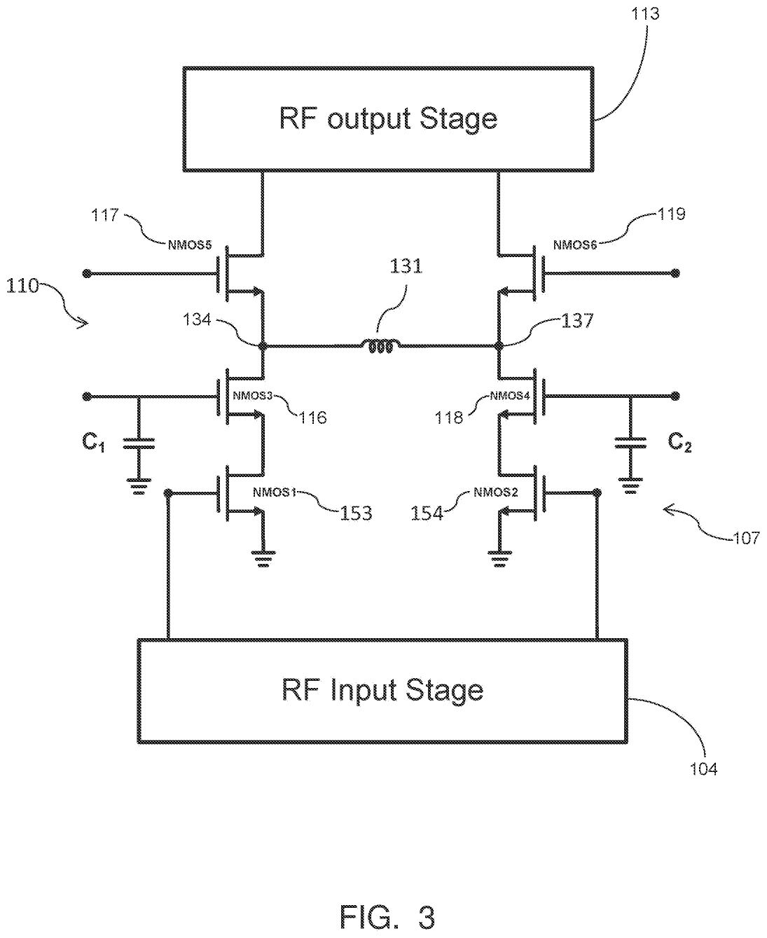

In FIG. 3, C1 and C2 represent all the extrinsic and intrinsic capacitance at the first and second nodes 134, 137, respectively. Since each pair of transistors is nominally the same (i.e., NMOS1=NMOS2; NMOS3=NMOS4; NMOS5=NMOS6) the parasitic capacitances is approximately the same (i.e., C1=C2, which is determined by a combination of C_{gd3}, C_{gs5}, C_{ds3}, C_{ds5}, C_{G1}). The inductor 131 creates an LC circuit and resonates out the parasitic capacitances at the first and second nodes 134, 137. The value for inductor 131 is chosen such that at desired operating frequency (f) the inductor resonates in a differential manner at the first and second nodes 134, 137 with the capacitors C1 and C2 boosting impedance and power gain according to the following formula:

f=1/(2×π×\sqrt{(L×C)}).

It is anticipated that the power amplifier circuit 101 having a single inductor 131 connected differentially between parallel paths of the power stage 110 will have an operating frequency approximately in the range of 76 GHz-81 GHz.

For electronic applications, semiconducting substrates, such as silicon wafers, can be used. The substrate enables easy handling of the micro device through the many fabrication steps. Often, many individual devices are made together on one substrate and then singulated into separated devices toward the end of fabrication. In order to fabricate a microdevice, many processes are performed, one after the other, many times repeatedly. These processes typically include depositing a film, patterning the film with the desired micro features, and removing (or etching) portions of the film. For example, in memory chip fabrication, there may be several lithography steps, oxidation steps, etching steps, doping steps, and many others are performed. The complexity of microfabrication processes can be described by their mask count.

The methods as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While only one or a limited number of transistors are illustrated in the drawings, those ordinarily skilled in the art would understand that many different types transistor could be simultaneously formed with the embodiment herein and the drawings are intended to show simultaneous formation of multiple different types of transistors; however, the drawings have been simplified to only show a limited number of transistors for clarity and to allow the reader to more easily recognize the different features illustrated. This is not intended to limit this disclosure because, as would be understood by those ordinarily skilled in the art, this disclosure is applicable to structures that include many of each type of transistor shown in the drawings.

The terminology used herein is for the purpose of describing particular devices and methods only and is not intended to be limiting of this disclosure. As used herein, the singular forms “a”, “an”, and “the” are intended to include the plural forms as well, unless the context clearly indicates otherwise. It will be further understood that the terms “comprises”, “comprising”, “includes”, and “including”, when used in this specification, specify the presence of stated features, integers, steps, operations, elements, and/or components, but do not preclude the presence or addition of one or more other features, integers, steps, operations, elements, components, and/or groups thereof.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The corresponding structures, materials, acts, and equivalents of all means or step plus function elements in the claims below are intended to include any structure, material, or act for performing the function in combination with other claimed elements as specifically claimed. The descriptions of the various devices and methods herein have been presented for purposes of illustration but are not intended to be exhaustive or limited to the devices and methods disclosed. Many modifications and variations will be apparent to those of ordinary skill in the art without departing from the scope and spirit of the described devices and methods. The terminology used herein was chosen to best explain the principles of the devices and methods, the practical application or technical improvement over technologies found in the marketplace, or to enable others of ordinary skill in the art to understand the devices and methods disclosed herein.

While various examples are described herein, it will be appreciated from the specification that various combinations of elements, variations, or improvements therein may be made by those skilled in the art and are within the scope of the disclosure. In addition, many modifications may be made to adapt a particular situation or material to the teachings of the disclosed concepts without departing from the essential scope thereof. Therefore, it is intended that the concepts not be limited to the particular examples disclosed as the best mode contemplated for carrying out the devices and methods herein, but that the devices and methods will include all features falling within the scope of the appended claims.

1. A structure, comprising:
an output stage;
a driver stage; and
a power stage connected between the driver stage and the output stage, wherein the power stage comprises:
a first transistor and a second transistor connected in series between the driver stage and the output stage;
a third transistor and a fourth transistor connected in series between the driver stage and the output stage; and
an inductor having a first terminal electrically connected to a first node between the first transistor and the second transistor and a second terminal electrically connected to a second node between the third transistor and the fourth transistor.

2. The structure according to claim 1,
wherein the first transistor has a first gate, the second transistor has a second gate, the third transistor has a third gate, and the fourth transistor has a fourth gate,
wherein the first gate and the third gate receive a first gate voltage such that the first transistor and the third transistor comprise a first common-gate stage of the power stage, and
wherein the second gate and the fourth gate receive a second gate voltage such that the second transistor and the fourth transistor comprise a second common-gate stage of the power stage.

3. The structure according to claim 1, wherein the driver stage comprises:
a fifth transistor connected in series between the first transistor and ground, wherein the fifth transistor has a fifth gate; and
a sixth transistor connected in series between the third transistor and ground, wherein the sixth transistor has a sixth gate;
wherein the fifth gate is electrically connected to a junction between the third transistor and the sixth transistor, and
wherein the sixth gate is electrically connected to a junction between the first transistor and the fifth transistor.

4. The structure according to claim 3, wherein the driver stage further comprises:
a first neutralization capacitor connected between the fifth gate and the junction between the third transistor and the sixth transistor; and
a second neutralization capacitor connected between the sixth gate and the junction between the first transistor and the fifth transistor.

5. The structure according to claim 3, further comprising an input stage, wherein the driver stage is connected between the input stage and the power stage.

6. The structure according to claim 5, wherein the input stage comprises a radio frequency input transformer comprising:
a primary winding connected between a radio frequency input and ground; and
a secondary winding connected between the fifth gate and the sixth gate.

7. The structure according to claim 1, wherein the output stage comprises a radio frequency output transformer comprising:
a primary winding connected between the second transistor and the fourth transistor; and
a secondary winding connected between a radio frequency output and ground.

8. A structure comprising:
an output stage;
a driver stage; and
a power stage connected between the driver stage and the output stage, wherein the power stage comprises:
a first transistor and a second transistor connected in series between the driver stage and the output stage;
a third transistor and a fourth transistor connected in series between the driver stage and the output stage; and
an inductor having a first terminal electrically connected to a first node between the first transistor and the second transistor and a second terminal electrically connected to a second node between the third transistor and the fourth transistor,
wherein the first transistor has a first gate, the second transistor has a second gate, the third transistor has a third gate and the fourth transistor has a fourth gate,
wherein the first gate and the third gate receive a first gate voltage such that the first transistor and the second transistor comprise a first common-gate stage of the power stage,
wherein the second gate and the fourth gate receive a second gate voltage such that the second transistor and the fourth transistor comprise a second common-gate stage of the power stage, and
wherein the inductor is configured to provide impedance matching between the first common-gate stage and the second common-gate stage.

9. The structure according to claim 8, wherein the first transistor, the second transistor, the third transistor, and the fourth transistor comprise n-type field effect transistors.

10. The structure according to claim 8, wherein the driver stage comprises:
a fifth transistor connected in series between the first transistor and ground, wherein the fifth transistor has a fifth gate; and
a sixth transistor connected in series between the third transistor and ground, wherein the sixth transistor has a sixth gate,
wherein the fifth gate is electrically connected to a junction between the third transistor and the sixth transistor, and
wherein the sixth gate is electrically connected to a junction between the first transistor and the fifth transistor.

11. The structure according to claim 10, wherein the driver stage further comprises:
a first neutralization capacitor connected between the fifth gate and the junction between the third transistor and the sixth transistor; and
a second neutralization capacitor connected between the sixth gate and the junction between the first transistor and the fifth transistor.

12. The structure according to claim 10, further comprising an input stage, wherein the driver stage is connected between the input stage and the power stage.

13. The structure according to claim 12, wherein the input stage comprises a radio frequency input transformer comprising:
a primary winding connected between a radio frequency input and ground; and
a secondary winding connected between the fifth gate and the sixth gate.

14. The structure according to claim 8, wherein the output stage comprises a radio frequency output transformer comprising:
a primary winding connected between the second transistor and the fourth transistor; and
a secondary winding connected between a radio frequency output and ground.

15. A structure comprising: an output stage;
a driver stage; and
a power stage connected between the driver stage and the output stage, wherein the power stage comprises:
a first transistor and a second transistor connected in series between the driver stage and the output stage;
a third transistor and a fourth transistor connected in series between the driver stage and the output stage; and
an inductor having a first terminal electrically connected to a first node between the first transistor and the second transistor and a second terminal electrically connected to a second node between the third transistor and the fourth transistor,
wherein the first transistor, the second transistor, the third transistor, and the fourth transistor comprise n-type field effect transistors,
wherein the first transistor has a first gate, the second transistor has a second gate, the third transistor has a third gate and the fourth transistor has a fourth gate,
wherein the first gate and the third gate receive a first gate voltage such that the first transistor and the second transistor comprise a first common-gate stage of the power stage,
wherein the second gate and the fourth gate receive a second gate voltage such that the second transistor and the fourth transistor comprise a second common-gate stage of the power stage, and
wherein the inductor is configured to provide impedance matching between the first common-gate stage and the second common-gate stage.

16. The structure according to claim 15, wherein the driver stage comprises:
a fifth transistor connected in series between the first transistor and ground, wherein the fifth transistor has a fifth gate; and
a sixth transistor connected in series between the third transistor and ground, wherein the sixth transistor has a sixth gate,
wherein the fifth gate is electrically connected to a junction between the third transistor and the sixth transistor, and
wherein the sixth gate is electrically connected to a junction between the first transistor and the fifth transistor.

17. The structure according to claim 16, wherein the driver stage further comprises:
a first neutralization capacitor connected between the fifth gate and the junction between the third transistor and the sixth transistor; and
a second neutralization capacitor connected between the sixth gate and the junction between the first transistor and the fifth transistor.

18. The structure according to claim 16, further comprising an input stage, wherein the driver stage is connected between the input stage and the power stage.

19. The structure according to claim 18, wherein the input stage comprises a radio frequency input transformer comprising:
a primary winding connected between a radio frequency input and ground; and a secondary winding connected between the fifth gate and the sixth gate.

20. The structure according to claim 15, wherein the output stage comprises a radio frequency output transformer comprising:
a primary winding connected between the second transistor and the fourth transistor; and
a secondary winding connected between a radio frequency output and ground.
